(19) United States
(12) Patent Application Publication
(10) Pub. No.: US 2009/0011545 A1
(43) Pub. Date: Jan. 8, 2009

(54) CHIP PACKAGE PROCESS

(75) Inventors: Chia-Wen Chiang, Hsinchu City (TW); Shou-Lung Chen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/195,394

(22) Filed: Aug. 20, 2008

Related U.S. Application Data
(62) Division of application No. 11/308,658, filed on Apr. 19, 2006.

(30) Foreign Application Priority Data
Dec. 30, 2005 (TW) 94147521

(51) Int. Cl. H01L 21/58

(52) U.S. Cl. 438/118; 257/E21.505

(57) ABSTRACT

The present invention further provides a chip package process, which includes providing a substrate, disposing a chip on the substrate and forming a buffering compound on the substrate and the chip, wherein the buffering compound covers the chip. The present invention further provides another chip package process, which includes providing a substrate, forming a buffering compound on the substrate and disposing a chip in the buffering compound.

### CROSS-REFERENCE TO RELATED APPLICATION

This application is a divisional of an application Ser. No. 11/308,658, filed on Apr. 19, 2006, now pending, which claims the priority benefit of Taiwan application serial no. 94147521, filed on Dec. 30, 2005. The entirety of each of the above-mentioned patent applications is hereby incorporated by reference herein and made a part of this specification.

### BACKGROUND OF THE INVENTION

1. Field of Invention

The present invention relates to a semiconductor device and a method for fabricating the same, and particularly to a chip package structure and a chip package process.

2. Description of the Related Art

In recent years, thanks to the electronic technology update in tremendous pace and the arisen semiconductor industry, massive upgraded electronic products with more humanized and powerful functions heading light, slim, short, small tendency are lunched and put into market. The chip packaging in the semiconductor industry is intended to protect dies from outside effects of moisture, heat and electrical noise and to provide the dies and external circuits thereof, for example a printed circuit board (PCB) or a substrate for packaging, with an electrical connection to each other.

Referring to FIG. 1, it is a schematic drawing of a conventional chip package structure, wherein a chip package structure 100 includes a chip 110, a substrate 120 and a dielectric material 130. The chip 110 is disposed on the substrate 120, while the dielectric material 130 is disposed on the same surface of the substrate 120 as the chip 110 and covers the chip 110 for protecting the chip 110 from outside effects of moisture, heat and electrical noise and further from external mechanical damage. Besides, the chip 110 is electrically connected to the substrate 120 by means of various connection ways, and then electrically connected to an external circuit through the contacts (not shown) on the bottom of the substrate 120. The chip 110 can be alternatively coupled to the contacts by interconnection traces formed inside the dielectric material 130 as well, wherein the contacts are disposed on the surface of the dielectric material 130.

No matter what types the packaging might be, a dielectric material in high temperature and semi-fusing status, such as epoxy resin, must be provided, followed by die pressing and cooling, so as to form the dielectric material covering the chip. In such a processing, however, the different CTE (coefficient of thermal expansion) of the chip, the substrate and the dielectric material would produce different thermal strains during the chip package process or the reliability test and practical operation of the semiconductor device. In particular, the strains vary with the ambient temperature, which leads to various thermal stresses at the corresponding junctions between any two parts of the chip, the substrate and the dielectric material. Along with miniaturization of the chip package structure and increased circuit integration, the impact of the thermal stresses becomes more noticeable, which may cause a serious warpage of the substrate, a damage of contact pads or a nonalignment between the chip and the substrate. Further, more seriously, a significant thermal stress leads the chip to be delaminated from the substrate and the package to be deformed. All these flaws seriously affect the normal operation of the chip and the production yield of the packaging.

### SUMMARY OF THE INVENTION

Based on the above described, the present invention is directed to provide a chip package structure capable of effectively reducing thermal stress and having higher reliability.

The present invention is further directed to provide a chip package process capable of reducing thermal stress impact in the process and having a better production yield.

The present invention provides a chip package structure, which includes a chip and a buffering compound. Wherein, the chip has an active surface, a back surface opposite to the active surface and a plurality of side surfaces between the active surface and the back surface. Besides, the buffering compound is disposed on at least the active surface and the back surface, and the buffering compound has a Young's modulus between 1 MPa and 1 GPa.

In an embodiment of the present invention, the buffering compound includes, for example, a first buffering layer and a second buffering layer, wherein the first buffering layer is disposed on the chip active surface, while the second buffering layer is disposed on the chip back surface. In another embodiment, the first buffering layer and the second buffering layer are, for example, extended to the chip side surfaces to join one another for encapsulating the chip.

In an embodiment of the present invention, the material of the first buffering layer and the material of the second buffering layer are the same.

In an embodiment of the present invention, the buffering compound further includes a third buffering layer, disposed on the chip side surface and joined to the first buffering layer and the second buffering layer for encapsulating the chip. In addition, the first buffering layer, the second buffering layer and the third buffering layer are made of the same material.

In an embodiment of the present invention, the chip package structure further includes a plurality of contacts and a plurality of interconnection traces, wherein the contacts are disposed on the surface of the buffering compound, while the interconnection traces are disposed inside the buffering compound for coupling the chip and the contacts.

In an embodiment of the present invention, the chip package structure further includes a substrate, over which the chip rests, and the chip and the substrate are spaced by the buffering compound.

In the above-described embodiment, the chip package structure further includes a dielectric material disposed on the substrate and covering the buffering compound and the chip, wherein the Young's modulus of the dielectric material is greater than the Young's modulus of the buffering compound. In addition, the chip package structure further includes a plurality of contacts and a plurality of interconnection traces, wherein the contacts are disposed on the surface of the dielectric material, while the interconnection traces are disposed inside the buffering compound and the dielectric material for coupling the chip and the contacts.

In an embodiment of the present invention, the material of the buffering compound is, for example, rubber or silicon.

The present invention further provides a chip package process, which includes providing a substrate, disposing a chip on the substrate and forming a buffering compound on the substrate and the chip, wherein the buffering compound covers the chip.

In an embodiment of the present invention, the method for disposing the chip includes disposing an adhesion layer between the chip and the substrate, so that the chip and the substrate are joined together through the adhesion layer.

In an embodiment of the present invention, the chip package process includes forming a plurality of interconnection traces inside the buffering compound, so as to make the chip connect to outside through the interconnection traces.

In an embodiment of the present invention, the chip package process further includes forming a dielectric material on the substrate for covering the buffering compound and the chip. In addition, the chip package process also forms a plurality of interconnection traces inside the buffering compound and the dielectric material, so as to make the chip connect to outside through the interconnection traces.

The present invention further provides another chip package process, which includes providing a substrate, forming a buffering compound on the substrate and disposing a chip in the buffering compound.

In an embodiment of the present invention, the above-described another chip package process further includes forming a plurality of interconnection traces inside the buffering compound, so as to make the chip connect to outside through the interconnection traces.

In an embodiment of the present invention, the above-described another chip package process further includes forming an dielectric material on the substrate for covering the buffering compound and the chip. In addition, the chip package process also forms a plurality of interconnection traces inside the buffering compound and the dielectric material, so as to make the chip connect to outside through the interconnection traces.

From the above described it can be seen that the present invention disposes a buffering compound surrounding the chip for smoothing thermal stresses, therefore the present invention is able to effectively reduce the substrate warpage and avoid the chip from stress damage or delaminating out of the substrate, which consequently further advance the packaging process yield and product reliability.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a schematic drawing of a conventional chip package structure.

FIG. 2 is a schematic drawing of a chip package structure provided by an embodiment of the present invention.

FIG. 3A˜FIG. 3E are schematic drawings showing a chip package process according to an embodiment of the present invention.

FIG. 4A˜FIG. 4E are schematic drawings showing another chip package process according to an embodiment of the present invention.

FIG. 5˜FIG. 9 are diagrams showing other different arrangements of buffering compound of the present invention.

FIG. 10 and FIG. 11 respectively show a schematic drawing of a chip package structure provided by another embodiment of the present invention.

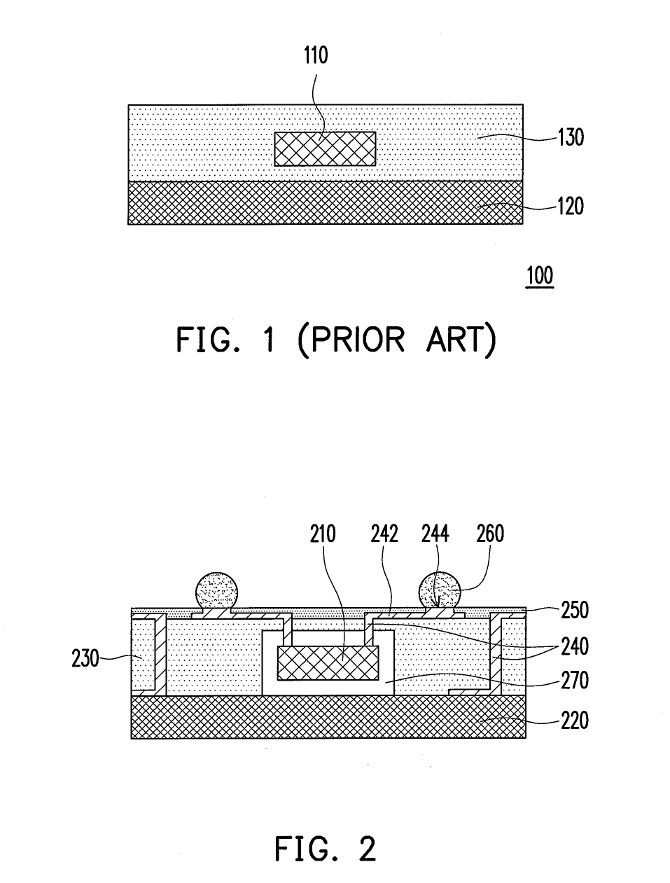

### DESCRIPTION OF THE EMBODIMENTS

FIG. 2 is a schematic drawing of a chip package structure provided by an embodiment of the present invention. Referring to FIG. 2, to provide a chip 210 with a stress buffering effect, surrounding the chip 210 a buffering compound 270 is disposed and the chip 210 is disposed over the substrate 220 through the buffering compound 270. In addition, a dielectric material 230 covers the buffering compound 270 and the chip 210 and in the buffering compound 270 and the dielectric material 230 a plurality of interconnection traces 240 is formed.

Referring to FIG. 2 again, a part of the interconnection traces 240 are connected to subsurface circuits 242 on the surface of the dielectric material 230, while a passivation layer 250 is disposed on the dielectric material 230 for exposing a part of the subsurface circuit 242 and using the exposed portions as a plurality of contacts 244. Besides, on the contacts 244, solder balls 260 are disposed, so that the chip 210 can be connected to an external circuit (not shown) through the interconnection traces 240, the subsurface circuits 242 and the solder balls 260.

In the present invention, the buffering compound 270 mainly serves for smoothing thermal stresses, therefore the Young's modulus thereof must be less than the one of the dielectric material 230, namely, the Young's modulus of the buffering compound 270 should be between a preferred range, from 1 MPa to 1 GPa. In the practice, rubber, silicon or other appropriate materials can be used to make buffering compound 270. In this way, the buffering compound 270 is capable of buffering stresses occurring, for example, between the chip 210 and the dielectric material 230 or between the chip 210 and the substrate 220.

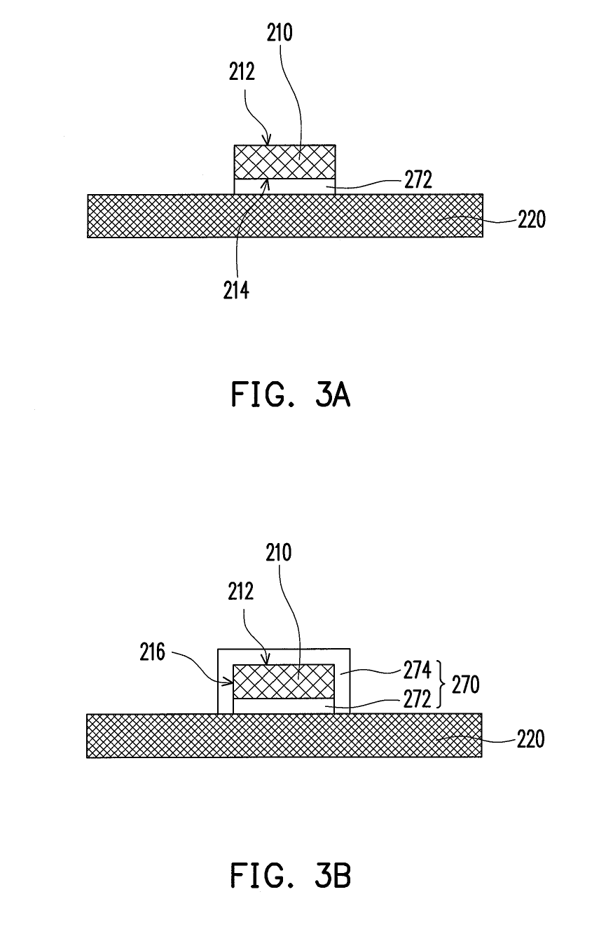

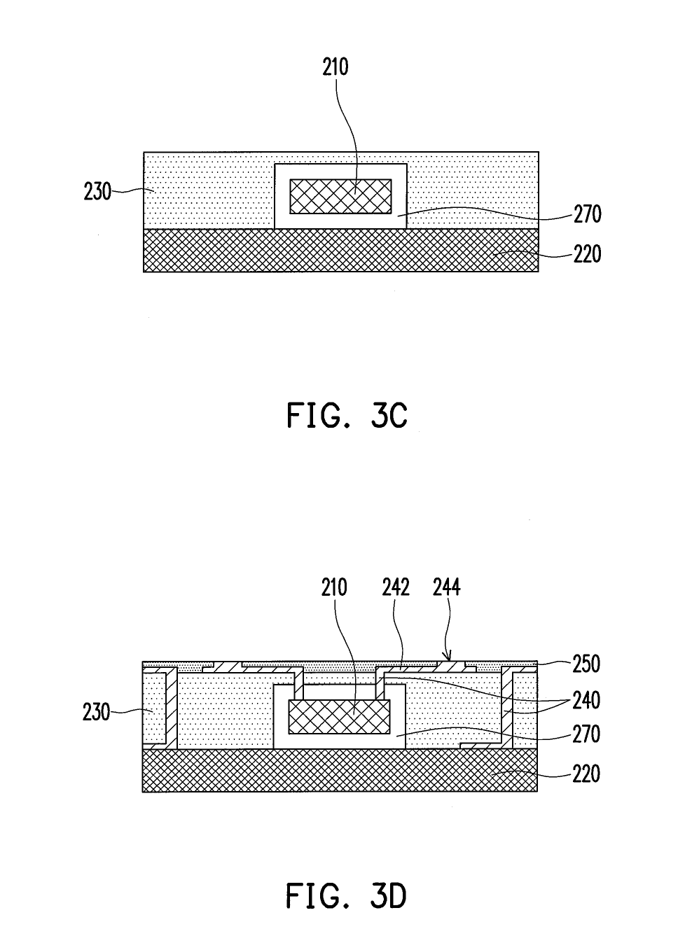

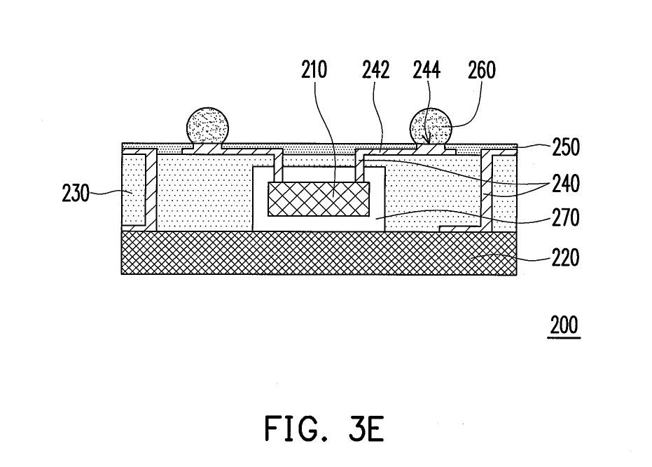

FIG. 3A˜FIG. 3E are schematic drawings showing a chip package process according to an embodiment of the present invention. The manufacturing process of the above-described chip package structure would be explained in more detail hereinafter.

First as shown in FIG. 3A, the chip 210 is disposed over the substrate 220, wherein the active surface 212 of the chip 210 faces upwards and the back surface 214 of the chip 210 connects the substrate 220 via an adhesion layer 272. The adhesion layer 272 herein can be formed on a wafer before dicing the wafer or formed by dispensing on the substrate 220. The material of the adhesion layer 272 in the present invention is, for example, a buffer material with Young's modulus between 1 MPa and 1 GPa.

Next as shown in FIG. 3B, a buffering layer 274 is formed on the chip 210, wherein the buffering layer 274 covers the active surface 212 and the side surfaces 216 of the chip 210 and joints the adhesion layer 272 to form a buffering compound 270 enclosing the chip 210. In the embodiment, the material of the buffering layer 274 can be the same material as the adhesion layer 272 or the different material from the adhesion layer 272. The Young's modulus of the material of the buffering layer is between 1 MPa and 1 GPa.

Afterwards as shown in FIG. 3C, on the substrate 220 a dielectric material 230 is formed, which covers the chip 210 and the buffering compound 270. The material of the dielectric material 230 usually is a dielectric material with a larger Young's modulus, for example, epoxy resin to provide a better protection and insulation effect.

Further as shown in FIG. 3D, interconnection traces 240 are formed in the dielectric material 230 and the buffering compound 270, and subsurface circuits 242 are formed on the surface of the dielectric material 230. Besides, a patterned passivation layer 250 is formed on the surface of the dielectric material 230, wherein the passivation layer 250 has a plurality of openings for exposing parts of the interconnection traces 240 to serve as contacts 244. Furthermore as shown in FIG. 3E, on each contact 244, a solder ball 260 is formed and at the point, the chip package structure 200 is roughly completed already, wherein the solder balls 260 serve for connecting the chip package structure 200 to an external circuit.

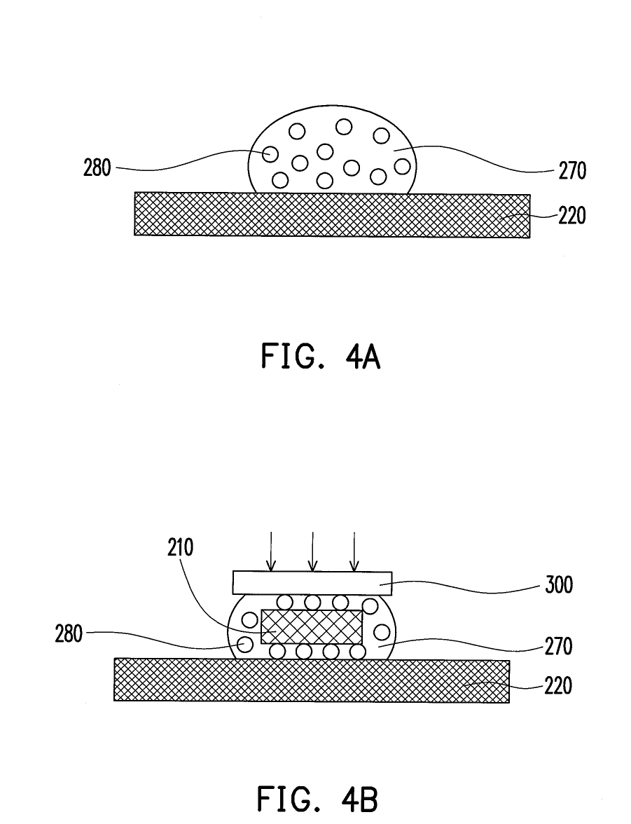

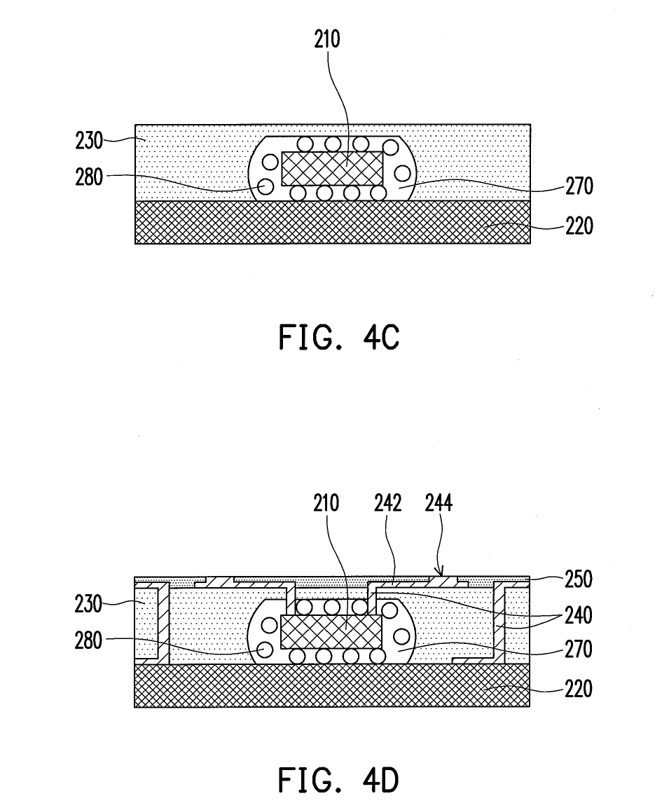

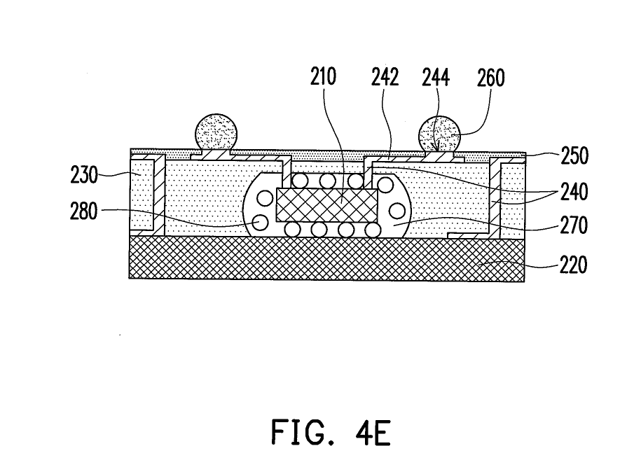

In addition, the present invention further provides a method for fabricating a chip package structure, referring to FIG. 4A˜FIG. 4E, which are schematic drawings showing another chip package process according to an embodiment of the present invention.

First as shown in FIG. 4A, a buffering compound 270 is disposed on the substrate 220, wherein the buffering compound 270 can be mingled with a plurality of spacers 280. The material of the buffering mingled 270 is, for example, rubber or silicon with Young's modulus between 1 MPa and 1 GPa. Next as shown in FIG. 4B, the chip 210 is put into the buffering mingled 270, followed by shaping the same using a fixture 300, wherein the spacers 280 assist the chip 210 to keep a right position in the buffering compound 270. Afterwards, the steps of the above-described embodiment are repeated for sequentially forming a dielectric material 230 (referring to FIG. 4C), fabricating interconnection traces 240 and subsurface circuits 242 (referring to FIG. 4D) and forming solder balls 260 at the contacts 244 (referring to FIG. 4E), then the another chip package process is completed.

In both the above-described chip package processes, the buffering compound 270 can be formed by two sub-steps (forming an adhesion layer 272 and forming a buffering layer 274) or by an one-off sub-step, where the buffering compound 270 is directly formed surrounding the chip 210. Certainly, the present invention does not limit the method for forming the buffering compound to the above-described two kinds; furthermore the buffering compound is not limited to a single material for forming purpose. In other words, the composition of the buffering compound or the sub-steps for fabricating the same can be modified depending on a practical demand and the best stress-buffering effect. Several different structures of the buffering compound are further explained in the following.

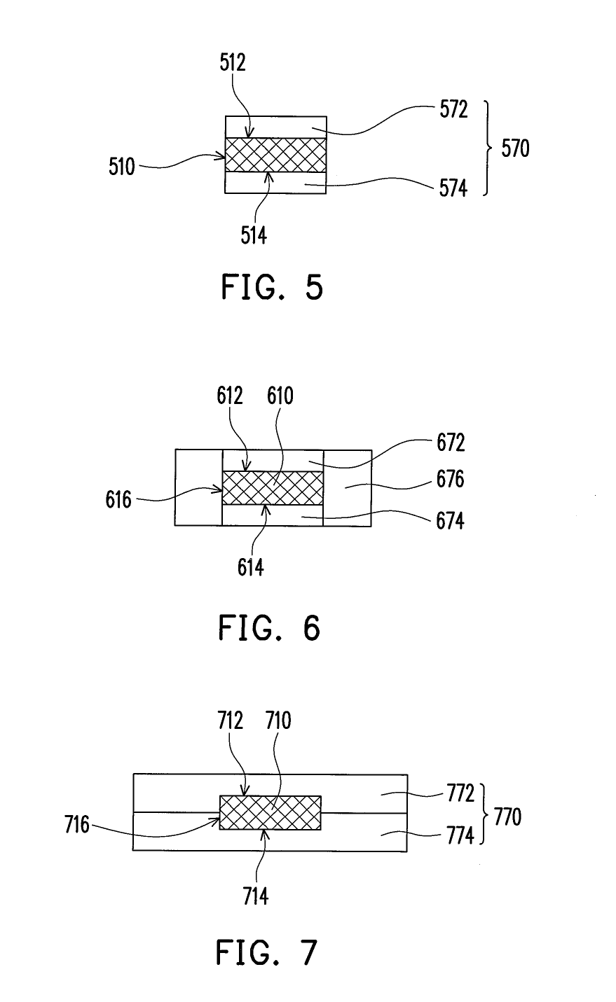

FIG. 5˜FIG. 9 are diagrams showing other different arrangements of buffering compound of the present invention, wherein only a chip and a buffering compound are shown for simplicity purpose.

Referring to FIG. 5, a buffering compound 570 includes a first buffering layer 572 disposed on the active surface 512 of the chip 510 and a second buffering layer 574 (for example, an adhesion layer) disposed on the back surface 514 of the chip 510.

The buffering compound 670 in FIG. 6 includes a first buffering layer 672 disposed on the active surface 612 of the chip 610, a second buffering layer 674 disposed on the back surface 614 of the chip 610 and a third buffering layers 676 disposed on the side surfaces 614 of the chip 610. The first buffering layer 672, the second buffering layer 674 and the third buffering layer 676 are fabricated by different sub-steps and made of different materials.

FIG. 7 shows a buffering compound 770 formed by a first buffering layer 772 and a second buffering layer 774, wherein the two buffering layers are made of different materials, the first buffering layer 772 is disposed on the active surface 712 of the chip 710, the second buffering layer 774 is disposed on the back surface 714 of the chip 710, and the first buffering layer 772 and the second buffering layer 774 are further extended to the side surfaces 716 of the chip 710 and are joined therein for encapsulating the chip 710. In terms of fabricating, the second buffering layer 774 is, for example, provided first, followed by burying a portion of the chip 710 into the buffering layer 774; then, the first buffering layer 772 is formed on the second buffering layer 774 to cover the chip 710.

FIG. 8 shows a buffering compound 870 similar to FIG. 7, that is to say the buffer compound 870 is formed by a first buffering layer 872 and a second buffering layer 874, and the two buffering layers are made of different materials. The second buffering layer 874 is disposed on the back surface 814 of the chip 810, the first buffering layer 872 is disposed on the active surface 812 of the chip 810, and the first buffering layer 872 and the second buffering layer 874 are further extended to the side surfaces 816 of the chip 810 for encapsulating the chip 810. Distinguished from FIG. 7, to fabricate the buffering compound 870 in FIG. 8, a first buffering layer 872 is provided first; then the chip 810 is put on the surface of the second buffering layer 874, followed by forming the first buffering layer 872 covering the chip 810 on the second buffering layer 872.

FIG. 9 shows a buffering compound 970 made of a single material. The buffering compound 970 encapsulates the chip 910 and can be formed by a single sub-step of molding or by a plurality of sub-steps, as the above-described embodiment, where the buffering layers are made of the same material.

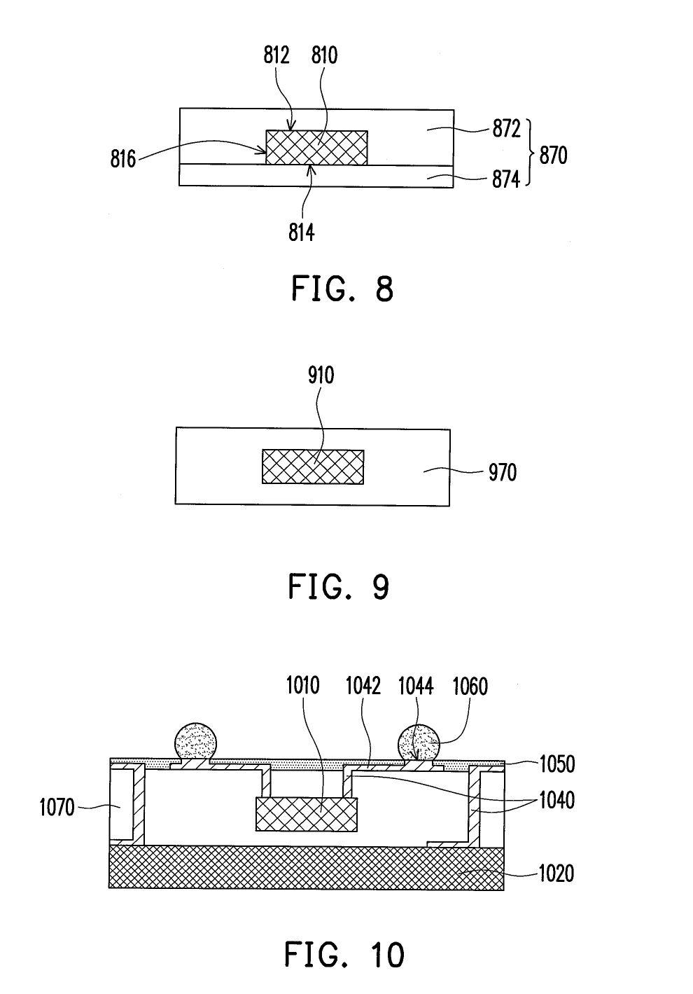

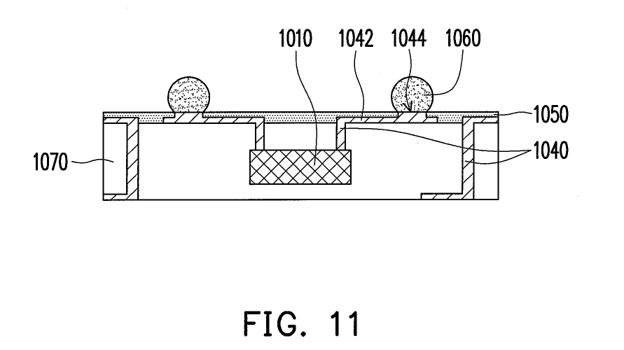

Note that if the dielectric property and the material strength of the buffering compound are within the permitted ranges, the present invention does not require to form an extra dielectric material, so as to simplify the process and save production cost. Referring to FIGS. 10 and 11, which respectively shows a schematic drawing of a chip package structure provided by another embodiment of the present invention. In FIG. 10, a chip 1010 is encapsulated by a buffering compound 1070 and the buffering compound 1070 is disposed on a substrate 1020. Additionally, FIG. 11 illustrates another chip package structure without the substrate 1020. Referring to both FIG. 10 and FIG. 11, a plurality of interconnection traces 1040 are disposed in the buffering compound 1070 and connected to subsurface circuits 1042 on the surface of the buffering compound 1070. A passivation layer 1050 is disposed on the surface of the buffering compound 1070 to expose the partial subsurface circuits 1042 and the exposed portions serve as a plurality of contacts 1044. Besides, on the contacts 1044 a plurality of solder balls 1060 are disposed, respectively, so that the chip 1010 is able to connect an external circuit (not shown) via the interconnection traces 1040, the subsurface circuits 1042 and the solder balls 1060. In the embodiment, the buffering compound 1070 allows to take different types as shown in FIGS. 6˜9, the material of the buffering compound 1070 has a Young's modulus between 1 MPa and 1 GPa and is, for example, rubber, silicon or other appropriate materials.

Except for the above-described embodiments, the buffering compound of the present invention can be applicable to other type package structures to solve the problem caused by thermal stresses between the chip and other package components. For those skilled in the art, the modifications to meet requirements of their own are not an issue, if the scheme of the present invention is referred.

In summary, the present invention is able to provide a solid solution of buffering thermal stresses by means of disposing a buffering compound surrounding the chip. Therefore, the chip package structure provided by the present invention can effectively reduce substrate warpage and prevent the chip from stress damage or being delaminated out of the substrate. Hence, the chip package structure of the present invention has better reliability. Moreover, based on the same reason, the chip packaging process of the present invention features higher production yield.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A chip package process, comprising:
providing a substrate;
disposing a chip over the substrate; and
forming a buffering compound on the substrate and the chip, wherein the buffering compound covers the chip.

2. The chip package process as recited in claim 1, wherein the step for disposing the chip over the substrate comprises disposing an adhesion layer between the chip and the substrate for the chip to connect the substrate through the adhesion layer.

3. The chip package process as recited in claim 1, further comprising forming a plurality of interconnection traces in the buffering compound for the chip to connect outside through the interconnection traces.

4. The chip package process as recited in claim 1, further comprising forming a dielectric material on the substrate to cover the buffering compound and the chip.

5. The chip package process as recited in claim 4, further comprising forming a plurality of interconnection traces in the buffering compound and the dielectric material for the chip to connect outside through the interconnection traces.

6. A chip package process, comprising:
providing a substrate;
forming a buffering compound on the substrate; and
disposing a chip in the buffering compound.

7. The chip package process as recited in claim 6, further comprising forming a plurality of interconnection traces in the buffering compound for the chip to connect outside through the interconnection traces.

8. The chip package process as recited in claim 6, further comprising forming a dielectric material on the substrate to cover the buffering compound and the chip.

9. The chip package process as recited in claim 8, further comprising forming a plurality of interconnection traces in the buffering compound and the dielectric material for the chip to connect outside through the interconnection traces.
